(19) United States
(12) Patent Application Publication
(10) Pub. No.: US 2024/0012957 A1
(43) Pub. Date: Jan. 11, 2024

(54) UNIVERSAL SIMULATION TESTING FOR GENERALIZED SYSTEM UNDER TEST (SuT)

(71) Applicant: WOVEN ALPHA, INC., Tokyo (JP)

(72) Inventors: Anthony DECOSTANZO, Tokyo (JP); Mate KOVACS, Tokyo (JP)

(73) Assignee: WOVEN ALPHA, INC., Tokyo (JP)

(21) Appl. No.: 17/861,457

(22) Filed: Jul. 11, 2022

(51) Int. Cl. G06F 30/20

(52) U.S. Cl. CPC G06F 30/20

(57) ABSTRACT

A simulation system based on a vehicle system includes a simulation module configured to generate simulated sensor data, at least one mock component in connection with the simulation module, the at least one mock component configured to simulate operation of a module of the vehicle system, and at least one testing hardware component in connection with the simulation module and the at least one mock component, the operation of which is tested during operation of the simulation system based on the generated simulated sensor data.

### BACKGROUND

### 1. Field

The disclosure relates generally to a system and method providing a universal testing strategy.

### 2. Description of Related Art

In a system under test (SuT), a developer utilizes a simulator to test component(s) of a system. In a typical SuT scenario, the developer determines which components to test and which components to simulate via a shim. In particular, for vehicle instrumentation, a developer may determine to test a planning module, and then simulate a perception module and localization module by way of an input shim, and simulate a controller by way of an output shim.

However, this SuT configuration includes several issues. First, the shims are software components that are permanently constructed without customization options, meaning that once the SuT is completed, the developer cannot change the fidelity of the shims for different testing purposes (i.e., a new shim must be constructed, which is a major inefficiency. Second, since the teams that construct the perception modules, localization modules, planning modules, and controllers and other components are usually separate entities, the construction of the SuT configuration is slow. Furthermore, the shim components are constructed in an ad hoc fashion, rendering the SuT process costly. In addition, there is typically no universal interface language or communication between the components of the system, meaning that the constructed shims cannot be easily interchanged or integrated into new SuT configurations.

### SUMMARY

According to an aspect of an example embodiment, a simulation system based on a vehicle system may include a simulation module configured to generate simulated sensor data, at least one mock component in connection with the simulation module, the at least one mock component configured to simulate operation of a module of the vehicle system, and at least one testing hardware component in connection with the simulation module and the at least one mock component, the operation of which is tested during operation of the simulation system based on the generated simulated sensor data.

According to an aspect of an example embodiment, a method of a simulation system may include generating, by a simulation module, simulated sensor data, simulating, by at least one mock component in connection with the simulation module, operation of a module of a vehicle system, and testing, during operation of the simulation system and based on the generated simulated sensor data, at least one testing hardware component in connection with the simulation module and the at least one mock component.

According to an aspect of an example embodiment, a non-transitory computer-readable storage medium may store instructions that, when executed by at least one processor, cause the at least one processor to generate, by a simulation module, simulated sensor data, simulate, by at least one mock component in connection with the simulation module, operation of a module of a vehicle system, and test, during operation of the simulation system and based on the generated simulated sensor data, at least one testing hardware component in connection with the simulation module and the at least one mock component.

Additional aspects will be set forth in part in the description that follows and, in part, will be apparent from the description, or may be learned by practice of the presented embodiments of the disclosure.

### BRIEF DESCRIPTION OF THE DRAWINGS

The above and other aspects, features, and aspects of embodiments of the disclosure will be more apparent from the following description taken in conjunction with the accompanying drawings, in which:

FIG. 1 is a diagram of devices of a system according to an embodiment;

FIG. 2 is a diagram of components of the devices of FIG. 1 according to an embodiment;

FIG. 3 is a diagram of a vehicle system, according to an embodiment;

FIG. 4 is a diagram of a simulation system, according to an embodiment; and

FIG. 5 is a flowchart of a method of a simulation system, according to an embodiment.

### DETAILED DESCRIPTION

The following detailed description of example embodiments refers to the accompanying drawings. The same reference numbers in different drawings may identify the same or similar elements.

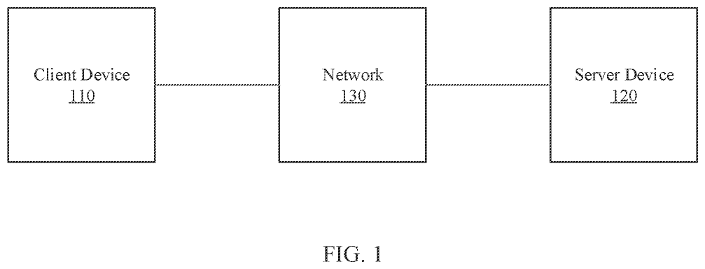

FIG. 1 is a diagram of a system according to an embodiment. FIG. 1 includes a client device 110, a server device 120, and a network 130. The client device 110 and the server device 120 may interconnect via wired connections, wireless connections, or a combination of wired and wireless connections.

The client device 110 may include a computing device (e.g., a desktop computer, a laptop computer, a tablet computer, a handheld computer, a smart speaker, a server device, etc.), a mobile phone (e.g., a smart phone, a radiotelephone, etc.), a camera device, a wearable device (e.g., a pair of smart glasses or a smart watch), or a similar device.

The server device 120 includes one or more devices. For example, the server device 120 may be a server device, a computing device, or the like.

The network 130 includes one or more wired and/or wireless networks. For example, network 130 may include a cellular network (e.g., a fifth generation (5G) network, a long-term evolution (LTE) network, a third generation (3G) network, a code division multiple access (CDMA) network, etc.), a public land mobile network (PLMN), a local area network (LAN), a wide area network (WAN), a metropolitan area network (MAN), a telephone network (e.g., the Public Switched Telephone Network (PSTN)), a private network, an ad hoc network, an intranet, the Internet, a fiber optic-based network, or the like, and/or a combination of these or other types of networks.

The number and arrangement of devices and networks shown in FIG. 1 are provided as an example. In practice, there may be additional devices and/or networks, fewer devices and/or networks, different devices and/or networks, or differently arranged devices and/or networks than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) may perform one or more functions described as being performed by another set of devices.

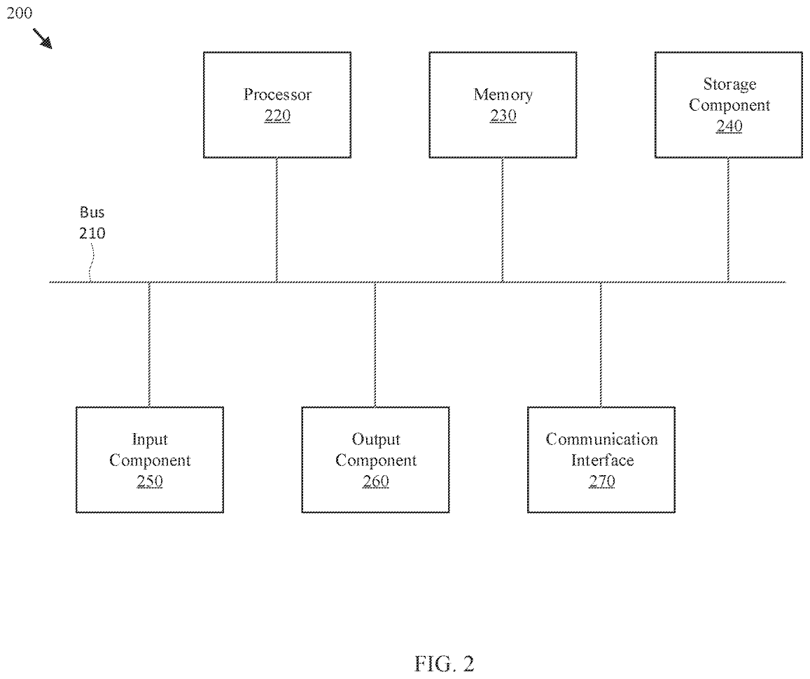

FIG. 2 is a diagram of components of one or more devices of FIG. 1 according to an embodiment. Device 200 may correspond to the client device 110 and/or the server device 120.

As shown in FIG. 2, the device 200 may include a bus 210, a processor 220, a memory 230, a storage component 240, an input component 250, an output component 260, and a communication interface 270.

The bus 210 includes a component that permits communication among the components of the device 200. The processor 220 is implemented in hardware, firmware, or a combination of hardware and software. The processor 220 is a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. The processor 220 includes one or more processors capable of being programmed to perform a function.

The memory 230 includes a random access memory (RAM), a read only memory (ROM), and/or another type of dynamic or static storage device (e.g., a flash memory, a magnetic memory, and/or an optical memory) that stores information and/or instructions for use by the processor 220.

The storage component 240 stores information and/or software related to the operation and use of the device 200. For example, the storage component 240 may include a hard disk (e.g., a magnetic disk, an optical disk, a magneto-optic disk, and/or a solid state disk), a compact disc (CD), a digital versatile disc (DVD), a floppy disk, a cartridge, a magnetic tape, and/or another type of non-transitory computer-readable medium, along with a corresponding drive.

The input component 250 includes a component that permits the device 200 to receive information, such as via user input (e.g., a touch screen display, a keyboard, a keypad, a mouse, a button, a switch, and/or a microphone). The input component 250 may include a sensor for sensing information (e.g., a global positioning system (GPS) component, an accelerometer, a gyroscope, and/or an actuator).

The output component 260 includes a component that provides output information from the device 200 (e.g., a display, a speaker, and/or one or more light-emitting diodes (LEDs)).

The communication interface 270 includes a transceiver-like component (e.g., a transceiver and/or a separate receiver and transmitter) that enables the device 200 to communicate with other devices, such as via a wired connection, a wireless connection, or a combination of wired and wireless connections. The communication interface 270 may permit device 200 to receive information from another device and/or provide information to another device. For example, the communication interface 270 may include an Ethernet interface, an optical interface, a coaxial interface, an infrared interface, a radio frequency (RF) interface, a universal serial bus (USB) interface, a Wi-Fi interface, a cellular network interface, or the like.

The device 200 may perform one or more processes described herein. The device 200 may perform operations based on the processor 220 executing software instructions stored by a non-transitory computer-readable medium, such as the memory 230 and/or the storage component 240. A computer-readable medium is defined herein as a non-transitory memory device. A memory device includes memory space within a single physical storage device or memory space spread across multiple physical storage devices.

Software instructions may be read into the memory 230 and/or the storage component 240 from another computer-readable medium or from another device via the communication interface 270. When executed, software instructions stored in the memory 230 and/or storage component 240 may cause the processor 220 to perform one or more processes described herein.

Additionally, or alternatively, hardwired circuitry may be used in place of or in combination with software instructions to perform one or more processes described herein. Thus, embodiments described herein are not limited to any specific combination of hardware circuitry and software.

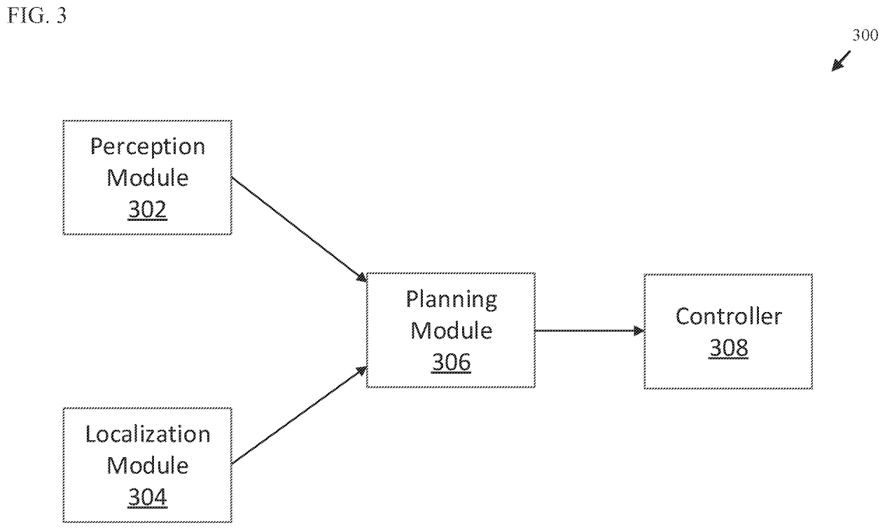

FIG. 3 is a diagram of a vehicle system 300, according to an embodiment. Although FIG. 3 depicts a vehicle system, the embodiments of the disclosure are not limited to a vehicle environment and may be implemented in other testing environments as will be understood by those of skill in the art. The vehicle system 300 may include a perception module 302 that fuses information received from sensors into a coherent representation of the environment and a localization module 304 that determines location information of the vehicle based on information received from sensors. The vehicle system 300 may also include a planning module 306 that determines a strategic approach to achieve a particular goal based on data from the perception module 302 and the localization module 304 (e.g., finding an appropriate route). The vehicle system 300 may also include a controller 308 that receives the strategy information from the planning module 306, determines appropriate commands for executing the approach determined by the planning module 306, and outputs the commands to actuators to execute the determined approach. The vehicle system 300 may also include additional modules that mediate signals between the aforementioned modules. The vehicle system can thus be considered to have arbitrarily many modules that participate in the pathway of converting information received from sensors into output commands to actuators.

To test at least one component of the system, a simulation system may be implemented in both hardware and software to efficiently and effectively test a system component or components (i.e., a system under test (SuT)). The component or components to be tested remain in the system as software or hardware, and the remaining components are replaced by mocks, which are software simulations of the untested hardware components.

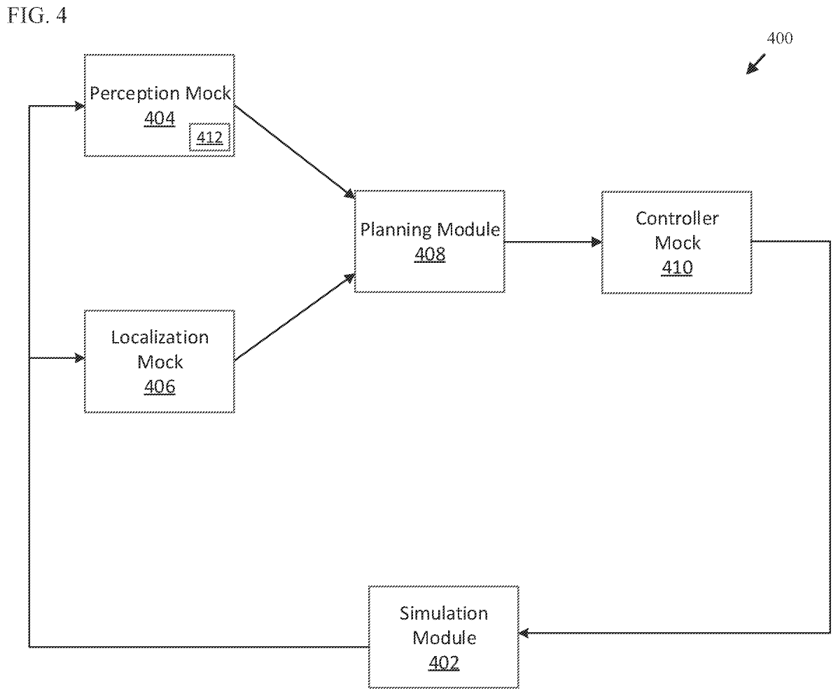

FIG. 4 is a diagram of a simulation system 400, according to an embodiment. In the example shown in FIG. 4, the planning module 408 is being tested (e.g., the planning module 306 of FIG. 3). However, additional or alternative components may be tested. The simulation system 400 may include a simulation module 402 that is configured to generate information that corresponds to the information generated by sensors, or other information that would be generated in a physical vehicle system (e.g., the vehicle system 300 of FIG. 3). In lieu of a shim, in one example, the simulation system 400 may include a perception mock 404 and a localization mock 406 that are connected to the simulation module. The perception mock 404 and the localization mock 406 are software simulations of the hardware and/or software perception module (e.g., the perception module 302 of FIG. 3) and the hardware and/or software localization module (e.g., the localization module 304 of FIG. 3), respectively. In this example, the planning module 408 is being tested in the simulation system 400, and therefore, the simulation system 400 may include the software and/or hardware planning module 408. The simulation system may also include a controller mock 410 which is a software simulation of the hardware and/or software controller (e.g., the controller 308 of FIG. 3). The controller mock 410 outputs the generated commands to the simulation module 402, and the simulation module 402 operates according to the generated commands to complete the test.

The components of the simulation system 400 are connected based on a universal interface language. As each component of the simulation system 400 may be constructed by different groups/teams that use different interface communications or programming languages, the basis of the universal interface language is provided to each team constructing the mocks and the hardware components being tested. The universal interface language allows for efficient and fast simulation testing because it stabilizes the codebase, forces an organization to make decisions centrally and plan architectures pre-emptively. This is adaptable to agile workflows.

In examples where all components that have interfaces with each other are written in the same programming language, then a universal interface language or interface description language (IDL) may not be needed. All that would be required is that the interface itself is defined (i.e., exactly which objects, such as data types, will be exchanged at the interface). It is of benefit if the interface is essentially fixed during the development. The more fixed the interface can be from generation to generation of the entire system, the better it will be for engineering development because teams can re-use the library of mock and real components. In examples where different component are written in different programming languages, then an IDL or universal interface language may be utilized. The language may be a language-independent description of types such that engineers working on components that share an interface may use different programming languages in each component, know that there will be a shared language for the interface (i.e., the IDL or universal interface language).

Furthermore, by having a universal interface language, the mocks may be customized, thereby changing properties of the simulation system without requiring a new mock to be constructed. For example, the mocks may be constructed with fidelity adjustments built in, or multiple mocks of varying fidelity may be constructed, allowing the fidelity of the mock in a particular test to be changed depending on the desired complexity of operation of the mock (e.g., the fidelity adjuster 412 of the perception mock 404). The universal interface language lowers the cost of making multiple compatible mocks of the same component.

Additionally, with the combination of software and hardware implementation, a number of components may be implemented as mocks while a number of components may be implemented as the original hardware and/or software components. For example, a simulation system may be constructed to test both the planning module (e.g., the planning module 306 of FIG. 3) and the controller (e.g., the controller 308 of FIG. 3), such that the simulation system includes a perception mock, localization mock, hardware and/or software planning module and hardware and/or software controller. In another example, a simulation system may be constructed to test the perception module (e.g., the perception module 302 of FIG. 3), the localization module (e.g., the localization module 304 of FIG. 3), and the controller (e.g., the controller 308 of FIG. 3), such that the simulation system includes a hardware and/or software perception module, a hardware and/or software localization module, a planning mock, and a hardware and/or software controller. This may be referred to as k-subset testing. Because all the components utilize a universal interface language, the software and hardware substitutions and combinations can be easily implemented while reducing the engineering costs of testing the systems.

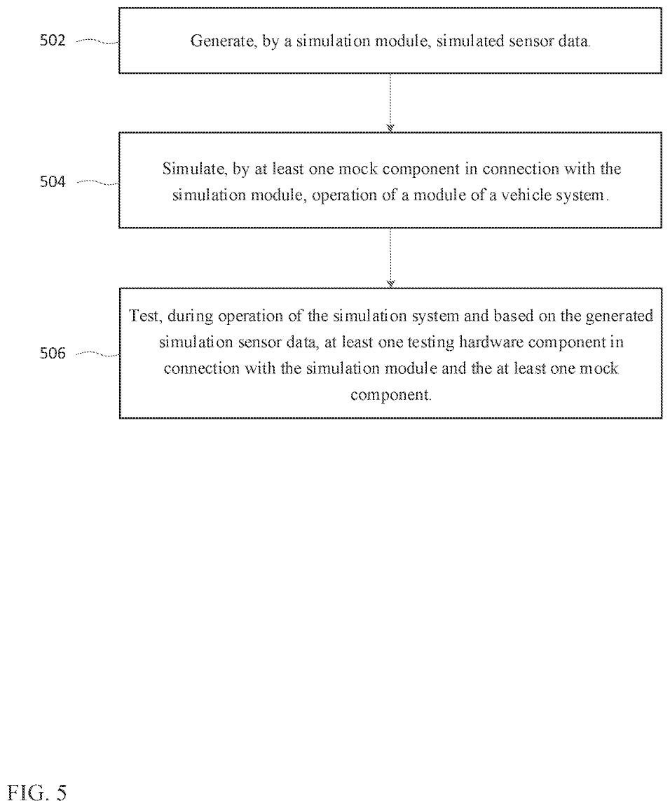

FIG. 5 is a flowchart of a method of a simulation system, according to an embodiment. In operation 502, the system generates, by a simulation module, simulated sensor data. In operation 504, the system simulates, by at least one mock component in connection with the simulation module, operation of a module of a vehicle system. In operation 506, the system tests, during operation of the simulation system and based on the generated simulated sensor data, at least one testing hardware component in connection with the simulation module and the at least one mock component.

The foregoing disclosure provides illustration and description, but is not intended to be exhaustive or to limit the implementations to the precise form disclosed. Modifications and variations are possible in light of the above disclosure or may be acquired from practice of the implementations.

Some embodiments may relate to a system, a method, and/or a computer readable medium at any possible technical detail level of integration. The computer readable medium may include a computer-readable non-transitory storage medium (or media) having computer readable program instructions thereon for causing a processor to carry out operations.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program code/instructions for carrying out operations may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects or operations.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer readable media according to various embodiments. In this regard, each block in the flowchart or block diagrams may represent a module, segment, or portion of instructions, which comprises one or more executable instructions for implementing the specified logical function(s). The method, computer system, and computer readable medium may include additional blocks, fewer blocks, different blocks, or differently arranged blocks than those depicted in the Figures. In some alternative implementations, the functions noted in the blocks may occur out of the order noted in the Figures. For example, two blocks shown in succession may, in fact, be executed concurrently or substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code—it being understood that software and hardware may be designed to implement the systems and/or methods based on the description herein.

No element, act, or instruction used herein should be construed as critical or essential unless explicitly described as such. Also, as used herein, the articles “a” and “an” are intended to include one or more items, and may be used interchangeably with “one or more.” Furthermore, as used herein, the term “set” is intended to include one or more items (e.g., related items, unrelated items, a combination of related and unrelated items, etc.), and may be used interchangeably with “one or more.” Where only one item is intended, the term “one” or similar language is used. Also, as used herein, the terms “has,” “have,” “having,” or the like are intended to be open-ended terms. Further, the phrase “based on” is intended to mean “based, at least in part, on” unless explicitly stated otherwise.

The descriptions of the various aspects and embodiments have been presented for purposes of illustration, but are not intended to be exhaustive or limited to the embodiments disclosed. Even though combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A simulation system based on a vehicle system, comprising:
a simulation module configured to generate simulated sensor data;
at least one mock component in connection with the simulation module, the at least one mock component configured to simulate operation of a module of the vehicle system; and
at least one testing hardware component in connection with the simulation module and the at least one mock component, the operation of which is tested during operation of the simulation system based on the generated simulated sensor data.

2. The simulation system of claim 1, wherein the simulation module, at least one mock component, and at least one testing hardware component are in connection based on a universal interface language.

3. The simulation system of claim 1, wherein the at least one mock component includes a fidelity adjuster that adjusts the complexity of operation of at least one mock component.

4. The simulation system of claim 1, wherein the at least one testing hardware component comprises a planning module configured to generate strategy information based on perception information and localization information.

5. The simulation system of claim 4, wherein the at least one mock component comprises a perception mock configured to generate the perception information based on the generated simulated sensor data.

6. The simulation system of claim 4, wherein the at least one mock component comprises a localization mock configured to generate the localization information based on the generated simulated sensor data.

7. The simulation system of claim 1, further comprising a controller mock configured to output at least one command generated by the at least one testing hardware component to the simulation module.

8. A method of a simulation system, comprising:
generating, by a simulation module, simulated sensor data;
simulating, by at least one mock component in connection with the simulation module, operation of a module of a vehicle system; and
testing, during operation of the simulation system and based on the generated simulated sensor data, at least one testing hardware component in connection with the simulation module and the at least one mock component.

9. The method of claim 8, wherein the simulation module, at least one mock component, and at least one testing hardware component are in connection based on a universal interface language.

10. The method of claim 8, wherein at least one mock component includes a fidelity adjuster that adjusts the complexity of operation of at least one mock component.

11. The method of claim 8, wherein at least one testing hardware component comprises a planning module configured to generate strategy information based on perception information and localization information.

12. The method of claim 11, wherein the at least one mock component comprises a perception mock configured to generate the perception information based on the generated simulated sensor data.

13. The method of claim 11, wherein the at least one mock component comprises a localization mock configured to generate the localization information based on the generated simulated sensor data.

14. The method of claim 8, further comprising outputting, by a controller mock, at least one command generated by the at least one testing hardware component to the simulation module.

15. A non-transitory computer-readable storage medium storing instructions that, when executed by at least one processor, cause the at least one processor to:
generate, by a simulation module, simulated sensor data;
simulate, by at least one mock component in connection with the simulation module, operation of a module of a vehicle system; and
test, during operation of the simulation system and based on the generated simulated sensor data, at least one testing hardware component in connection with the simulation module and the at least one mock component.

16. The storage medium of claim 15, wherein the simulation module, at least one mock component, and at least one testing hardware component are in connection based on a universal interface language.

17. The storage medium of claim 15, wherein at least one mock component includes a fidelity adjuster that adjusts the complexity of operation of at least one mock component.

18. The storage medium of claim 15, wherein at least one testing hardware component comprises a planning module configured to generate strategy information based on perception information and localization information.

19. The storage medium of claim 18, wherein the at least one mock component comprises a perception mock configured to generate the perception information based on the generated simulated sensor data.

20. The storage medium of claim 18, wherein the at least one mock component comprises a localization mock configured to generate the localization information based on the generated simulated sensor data.
